(19) United States
(12) Patent Application Publication
(10) Pub. No.: US 2008/0311867 A1
(43) Pub. Date: Dec. 18, 2008

(54) MOS RESISTANCE CONTROLLING DEVICE, MOS ATTENUATOR AND RADIO TRANSMITTER

(75) Inventors: Yuta Araki, Shibuya-ku (JP); Shoji Otaka, Yokohama-shi (JP); Toru Hashimoto, Yokohama-shi (JP)

Correspondence Address: AMIN, TUROCY & CALVIN, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/025,314

(22) Filed: Feb. 4, 2008

(30) Foreign Application Priority Data
Jun. 18, 2007 (JP) 2007-159634

(51) Int. Cl. H04B 1/04; H03L 5/00

(52) U.S. Cl. 455/127.2; 327/308

(57) ABSTRACT

A MOS resistance controlling device includes: a plurality of MOS transistors having a first MOS transistor to N-th (the integer N is larger than 1) MOS transistor being serially connected, the source of the first MOS transistor being set to a first reference potential, the drain the N-th MOS transistor being set to a second reference potential, and the drain of an I-th MOS transistor being connected to the source of an I+1-th MOS transistor, where I is an integer from 1 to N−1; a current source which is electrically disposed at connection node between the drain of the N-th MOS transistors and the second reference potential; and an operational amplifier having a first input terminal being supplied with a third reference potential, a second input terminal connected with the connection node and an output terminal being connected with gates of the MOS transistors.

### CROSS-REFERENCE TO RELATED APPLICATIONS

This application is based upon and claims the benefit of priority from the prior Japanese Patent Application No. 2007-159634, filed on Jun. 18, 2007; the entire contents of which are incorporated herein by reference.

### BACKGROUND OF THE INVENTION

1. Field of the Invention

The present invention relates to a MOS resistance controlling device for controlling the resistance between the source and drain of a MOS transistor, a MOS attenuator having the MOS resistance controlling device and a wireless transmitter having the MOS resistance controlling device.

2. Description of the Related Art

A MOS transistor is widely available as a resistance element for various electronic circuits. In this case, the linear region of the MOS transistor is utilized. In the linear region of the MOS transistor, the resistance “Rmos” between the drain and source of the MOS transistor can be approximately represented by the equation of Rmos≈1/{β(Vgs−Vth)}. Herein, β=(μnCox)(W/L) (μn: electron mobility, Cox: gate oxide capacitance per unit area, L: gate length of MOS transistor, W: gate width of MOS transistor, Vgs: voltage between gate and source of MOS transistor, Vth: threshold voltage). Therefore, the resistance “Rmos” can be varied by changing the gate voltage Vgs.

A MOS resistance controlling circuit is exemplified in Reference 1, and uses a feedback circuit with an operational amplifier. Schematically, the gate voltage to realize the intended MOS resistance is obtained through the feedback of the voltage between the source and drain of the MOS transistor to the operational amplifier. In this case, the gate voltage is applied to the gate of another MOS transistor so that another MOS transistor is controlled so as to have the intended MOS resistance.

A variable attenuator is disclosed in Reference 2 as an application circuit using the MOS resistance. Schematically, the MOS resistances are employed as a ground resistance and a passing resistance, respectively and the gate voltage of the ground MOS transistor is varied so as to realize the variable attenuator. Since the characteristic impedance of the attenuator is shifted from a predetermined value (rendered non-matching state) if only the ground resistance is changed, a prescribed voltage is applied to the gate of the passing MOS transistor so that the characteristic impedance of the attenuator is set to the predetermined value. In order to obtain the predetermined voltage, a dummy circuit (replica) with a circuit structure similar to the one of the variable attenuator and a feedback circuit with an operational amplifier are provided.

Another variable attenuator is disclosed in Reference 3 as an application circuit using the MOS resistance. In this case, the variable attenuator is configured such that the gate voltage of the passing MOS transistor is rendered variable by an external component, which is opposite of the variable attenuator disclosed in Reference 2. A prescribed voltage is applied to the gate of the ground MOS transistor so that a predetermined characteristic impedance of the attenuator can be maintained. The prescribed voltage is generated by an electronic circuit with a feedback circuit using an operational amplifier and a dummy circuit and supplied to the gate of the ground MOS transistor.

Generally, it is desired that in the variable attenuator to control the attenuation by an external component, the attenuation characteristic is determined as designed under no fluctuation (which is represented by the graphic shape of the attenuation depicted in an ordinate axis for the control input depicted in an abscissa axis). However, the fluctuation in attenuation of the attenuator may be generated by necessity originated from the characteristic fluctuation in each component manufacturing step. The teaching of the improvement for the fluctuation in attenuation of the attenuator is not disclosed and suggested in References 2 and 3.
[Reference 1] JP-A 10-200334 (KOKAI)
[Reference 2] Hakan Dogan, Robert G. Meyer and Ali M. Niknejad BWRC, UC Berkeley, “A DC-10 GHZ Linear-in-dB Attenuator in 0.13 μm CMOS Technology”, IEEE 2004 CUSTOM INTEGCONSTANT CIRCUITS CONFERENCE pp 609 to 612
[Reference 3] U.S. Pat. No. 4,975,604

### BRIEF SUMMARY OF THE INVENTION

It is an object of the present invention to provide a MOS resistance controlling device to enhance the precision of the variable characteristic as designed under no fluctuation in the case of the application of the MOS resistance controlling device as a MOS attenuator, a MOS attenuator having the MOS resistance controlling device and a wireless transmitter having the MOS resistance controlling device.

In order to achieve the above object, an aspect of the present invention relates to a MOS resistance controlling device, including: a MOS transistor of which a source is electrically connected with a first standard potential; a first controlling current source which is disposed between and connected with a drain of the MOS transistor and a second standard potential; an operational amplifier having a first input terminal, a second input terminal and an output terminal such that the first input terminal is connected with a connection node between the drain of the MOS transistor and the first controlling current source and the output terminal is connected with a gate of the MOS transistor; an impedance element of which one end is connected with the second input terminal of the operational amplifier; a standard current source for introducing a first current into the impedance element via the one end of the impedance element; a second controlling current source for introducing a second current into the impedance element via the one end of the impedance element; and a third controlling current source for introducing a third current into the drain of the MOS transistor.

In the MOS resistance controlling device according to the aspect, since the second controlling current source and the third controlling current source are provided, the variable characteristic of the MOS resistance for the output current from the first controlling current source can be changed as designed. The second controlling current source is configured so as to introduce a current into the impedance element via the one end of the impedance element. The third controlling current source is configured so as to introduce a current into the drain of the MOS transistor as the first controlling current source.

In the operational amplifier, the first input terminal is shorted imaginarily for the second input terminal. Therefore, when the output current of the second controlling current source is increased, the voltage at one end of the impedance element is increased so that the drain voltage of the MOS transistor is increased (that is, the resistance of the MOS transistor is increased). When the output current of the third controlling current source is increased, the resistance of the MOS transistor is decreased so that the current in the MOS transistor can be increased in accordance with the increase of the output current of the third controlling current source. In this way, the resistance of the MOS transistor can be increased or decreased by controlling the second controlling current source and the third controlling current source. As a result, the variable characteristic of the MOS attenuator having the MOS resistance controlling device can be compensated by the controlling voltage generated from the MOS resistance controlling device

Another aspect of the present invention relates to a MOS attenuator, including: a MOS transistor of which a source is electrically connected with a first standard potential; a first voltage controlling current source which is disposed between and connected with the drain of the MOS transistor and a second standard potential; a first operational amplifier having a first input terminal, a second input terminal and an output terminal such that the first input terminal is connected with a connection node between the drain of the MOS transistor and the first controlling current source and the output terminal is connected with a gate of the MOS transistor; an impedance element of which one end is connected with the second input terminal of the first operational amplifier; a standard current source for introducing a first current into the impedance element via the one end of the impedance element; a second voltage controlling current source for introducing a second current into the impedance element via the one end of the impedance element; a third voltage controlling current source for introducing a third current into the drain of the MOS transistor; a fourth voltage controlling current source for introducing a fourth current to the drain of the MOS transistor, a transconductance of the fourth voltage controlling current source being set coefficient times as large as a transconductance of the first voltage controlling current source; a first attenuator having an input terminal, an output terminal, a plurality of ground MOS transistors and at least one passing MOS transistor, the ground MOS transistors and the passing MOS transistor being disposed between the input terminal and the output terminal of the first attenuator, so that the output terminal of the first operational amplifier is connected with gates of the ground MOS transistors and a control voltage is supplied to a gate of the at least one passing MOS transistor so as to set a characteristic impedance between the input terminal and the output terminal to a predetermined value; a first resistor, electrically disposed between the input terminal of the first attenuator and a third reference potential, having an impedance corresponding to the characteristic impedance; a second resistor, electrically disposed between the output terminal of the first attenuator and a forth reference potential; a second operational amplifier to generate an amplified output signal in comparison with a voltage at the output terminal of the first attenuator and a predetermined voltage, and to output the amplified output signal as the control voltage; and a second attenuator having an input terminal, an output terminal, a plurality of ground MOS transistors and at least one passing MOS transistor, the ground MOS transistors and the passing MOS transistor being disposed between the input terminal and the output terminal of the second attenuator, so that the output terminal of the first operational amplifier is connected with gates of the ground MOS transistors and the control voltage is supplied to a gate of the at least one passing MOS transistor.

The MOS attenuator includes the function of the MOS resistance controlling device. Therefore, the controlling voltage for the MOS resistance controls the resistances of the ground MOS transistors in the second attenuator. As a result, the variable characteristic of the MOS attenuator can be compensated as described above.

Still another aspect of the present invention relates to a wireless transmitter, including: a baseband processing unit for generating two baseband signals: a quadrature modulator for orthogonally modulating two carrier signals orthogonal to one another using the baseband signals and thus, generating a modulated signal: a MOS attenuator including, a MOS transistor of which a source is electrically connected with a first standard potential; a first voltage controlling current source which is disposed between and connected with the drain of the MOS transistor and a second standard potential; a first operational amplifier having a first input terminal, a second input terminal and an output terminal such that the first input terminal is connected with a connection node between the drain of the MOS transistor and the first controlling current source and the output terminal is connected with a gate of the MOS transistor; an impedance element of which one end is connected with the second input terminal of the first operational amplifier; a standard current source for introducing a first current into the impedance element via the one end of the impedance element; a second voltage controlling current source for introducing a second current into the impedance element via the one end of the impedance element; a third voltage controlling current source for introducing a third current into the drain of the MOS transistor; a fourth voltage controlling current source for introducing a fourth current to the drain of the MOS transistor, a transconductance of the fourth voltage controlling current source being set coefficient times as large as a transconductance of the first voltage controlling current source; a first attenuator having an input terminal, an output terminal, a plurality of ground MOS transistors and at least one passing MOS transistor, the ground MOS transistors and the passing MOS transistor being disposed between the input terminal and the output terminal of the first attenuator, so that the output terminal of the first operational amplifier is connected with gates of the ground MOS transistors and a control voltage is supplied to a gate of the at least one passing MOS transistor so as to set a characteristic impedance between the input terminal and the output terminal to a predetermined value; a first resistor, electrically disposed between the input terminal of the first attenuator and a third reference potential, having an impedance corresponding to the characteristic impedance; a second resistor, electrically disposed between the output terminal of the first attenuator and a forth reference potential; a second operational amplifier to generate an amplified output signal in comparison with a voltage at the output terminal of the first attenuator and a predetermined voltage, and to output the amplified output signal as the control voltage; and a second attenuator having an input terminal, an output terminal, a plurality of ground MOS transistors and at least one passing MOS transistor, the ground MOS transistors and the passing MOS transistor being disposed between the input terminal and the output terminal of the second attenuator, so that the output terminal of the first operational amplifier is connected with gates of the ground MOS transistors and the control voltage is supplied to a gate of the at least one passing MOS transistor, the MOS attenuator being configured such that the modulated signal is input to the input terminal of the second attenuator and an attenuated and modulated signal is generated at the output terminal of the second attenuator: an electric power amplifier for amplifying in electric power the attenuated and modulated signal and thus, generating an amplified signal in electric power: and an antenna for emitting the amplified signal in electric power as an electromagnetic wave, wherein the baseband signal processing unit generates a controlling voltage for the first through the fourth voltage controlling current sources.

The wireless transmitter uses the MOS attenuator.

According to the aspects of the present invention can be provide a MOS resistance controlling device to enhance the precision of the variable characteristic as designed under no fluctuation in the case of the application of the MOS resistance controlling device as a MOS attenuator, a MOS attenuator having the MOS resistance controlling device and a wireless transmitter having the MOS resistance controlling device.

### BRIEF DESCRIPTION OF THE SEVERAL VIEWS OF THE DRAWINGS

FIG. 1 is a circuit diagram relating to a MOS resistance controlling device according to an embodiment.

FIG. 2 is a graph showing the change in control characteristic of the MOS resistance in the MOS resistance controlling device in FIG. 1.

FIG. 3 is a circuit diagram relating to a MOS resistance controlling device according to another embodiment.

FIG. 4 is a graph showing the change in control characteristic of the MOS resistance in the MOS resistance controlling device in FIG. 3.

FIG. 5 is a circuit diagram relating to a MOS resistance controlling device according to still another embodiment.

FIG. 6 is a circuit diagram relating to a MOS attenuator according to an embodiment.

FIG. 7 is a graph showing the change in variable attenuation characteristic of the MOS attenuator in the MOS attenuator in FIG. 6.

FIG. 8 is a block diagram showing the compensation in variable attenuation characteristic of the MOS attenuator in the MOS attenuator in FIG. 6.

FIG. 9 is a graph showing the compensation in variable attenuation characteristic of the MOS attenuator by the block diagram shown in FIG. 8.

FIG. 10 is a block diagram showing a concrete embodiment of the block diagram of the MOS attenuator.

FIG. 11 is a block diagram showing another concrete embodiment of the block diagram of the MOS attenuator.

FIG. 12 is a block diagram showing a structure of a wireless transmitter having the MOS attenuator shown in FIG. 6.

FIG. 13 is a block diagram showing another structure of a wireless transmitter having the MOS attenuator shown in FIG. 6.

### DETAILED DESCRIPTION OF THE INVENTION

### First Embodiment

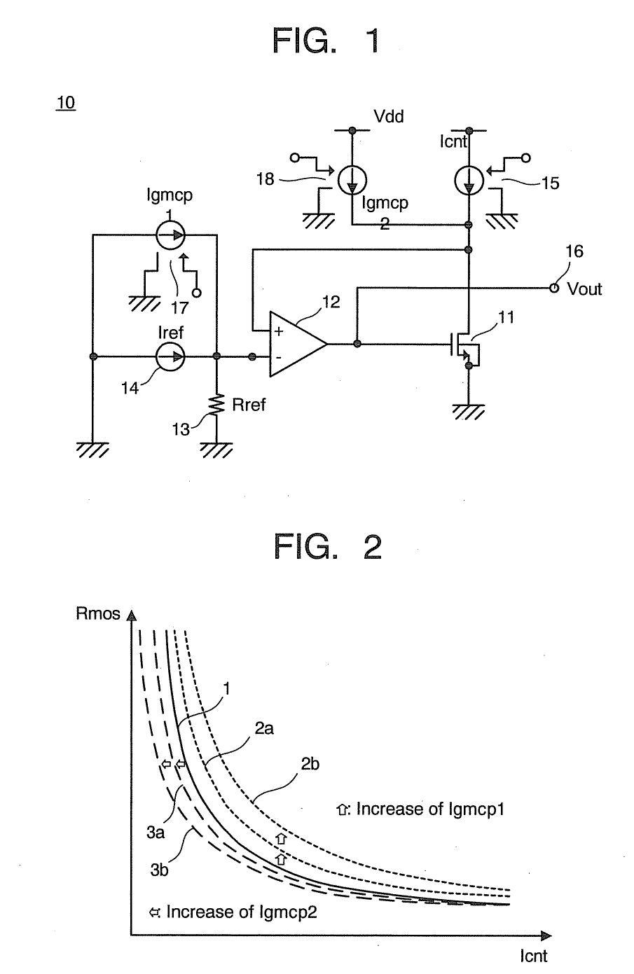

The first embodiment will be described with reference to the drawings. FIG. 1 is a circuit diagram relating to a MOS resistance controlling device according to the first embodiment. As shown in FIG. 1, the MOS resistance controlling device 10 includes a MOS transistor 11, an operational amplifier 12, a resistance 13 (impedance element), a standard current source 14, a voltage controlling current sources 15, 17, 18. The output of the operational amplifier 12 is supplied to the output terminal 16 of the MOS resistance controlling device 10 as an output Vout.

The MOS transistor (n-channel MOS transistor) 11 is configured such that the source of the MOS transistor 11 is electrically grounded and the semiconductor area (in the corresponding semiconductor substrate) for the channel of the MOS transistor 11 to be formed are electrically grounded, as depicted in FIG. 1. Then, the drain of the MOS transistor 11 is connected with one end of the voltage controlling current source 15 and an output voltage of the operational amplifier 12 is supplied to the gate of the MOS transistor 11.

The operational amplifier 12 includes two input terminals and an output terminal so that the output voltage of the standard current source 14 (Iref) is supplied as an inverting input to one of the input terminals of the operational amplifier 12 via the resistance 13 (Rref) because the output current of the standard current source 14 is flowed in the resistance 13 (Rref). Then, the voltage generated at the connection node between the drain of the MOS transistor 11 and the voltage controlling current source 15 is supplied as a non-inverting input to the other of the input terminals of the operational amplifier 12. The voltage controlling current source 15 is disposed between and connected with the drain of the MOS transistor 11 and the VDD (second standard potential) so as to supply the current Icnt to the MOS transistor 11.

If the voltage controlling current sources 17 and 18 are not provided, the resistance Rmos between the source and drain of the MOS transistor 11 is controlled only by the current Icnt output from the voltage controlling current source 15. Since the one of the input terminals is shorted imaginarily for the other of the input terminals so that the drain voltage of the MOS transistor 11 is maintained constant (=RrefIref), the resistance Rmos between the source and drain of the MOS transistor 11 is also changed when the current Icnt is changed. Namely, the Rmos=RrefIref/Icnt.

The Rmos can be depicted as shown in FIG. 2 when the abscissa axis designates the Icnt and the ordinate axis designates the Rmos. The Rmos characteristic is fluctuated by the characteristic fluctuation of each component in the MOS resistance controlling device 10. The gate voltage generating the Rmos for the MOS transistor 11 may be supplied to a gate of another MOS transistor via the output terminal 16 so that the Rmos of another MOS transistor can be set to a predetermined value.

In the MOS resistance controlling device 10, the voltage controlling current source 17 (Igmcp1) is connected in series with the standard voltage source 14 and the voltage controlling current source 18 (Igmcp1) is connected in series with the voltage controlling current source 15 so as to determine the Rmos characteristic to a prescribed value as designed. The function of the voltage controlling current sources 17 and 18 can be easily considered in view of the above-described equation. Namely, since the relation of the Rmos=Rref(Iref+Igmcp1)/(Icnt+Igmcp2) is provided, the curve “1” is shifted upward as depicted by the curves 2a, 2b when the Igmcp1 is increased from zero. Then, the curve “1” is shifted to the left as depicted by the curves 3a, 3b when the Igmcp2 is increased from zero.

Therefore, the Rmos characteristic can be changed from the initial curve 1 to some degrees. In this point of view, if the Rmos characteristic is fluctuated, the fluctuation of the Rmos characteristic can be compensated. Since the function of the Igmcp1 for the Rmos characteristic is different from the function of the Igmcp2 for the Rmos characteristic, the fluctuation compensation can be enhanced if the Igmcp1 and the Igmcp2 can be controlled independently. Moreover, if the typical values of the Igmcp1 and Igmcp2 are determined and the Igmcp1 and Igmcp2 can be decreased from the typical values, the fluctuation compensation can be enhanced.

The voltage controlling current sources 15, 17, 18 may be substituted with current controlling current sources, respectively. Moreover, each controlling current source may be configured so as to be controlled by digital quantity instead of the analog quantity such as voltage or current.

### Second Embodiment

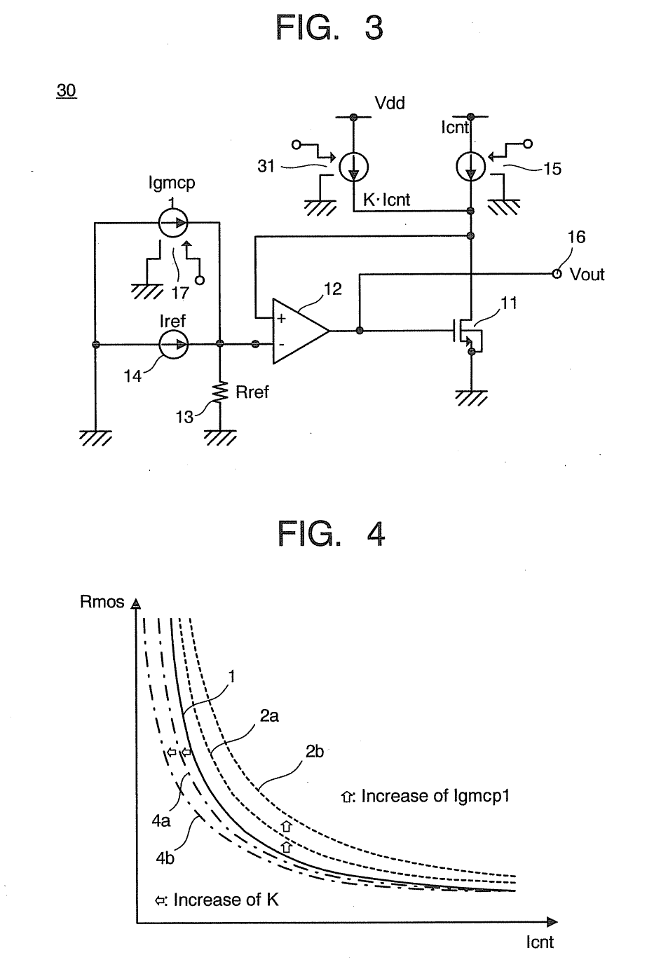

The second embodiment will be described with reference to the drawings. FIG. 3 is a circuit diagram relating to a MOS resistance controlling device according to the second embodiment. In this embodiment, like or corresponding component are designated by the same references and thus, omitted in explanation.

In the MOS resistance controlling device 30 in this embodiment, a voltage controlling current source 31 (KIcnt) is connected in series with the voltage controlling current source 15 instead of the voltage controlling current source 18 (Igmcp2). Namely, the voltage controlling current source 31 generates a coefficient times (K times) output voltage in accordance with the output current Icnt of the voltage controlling current source 15.

In this case, since the relation of the Rmos=Rref(Iref+Igmcp1)/{(1+K)Icnt} is provided, in FIG. 4, the curve “1” is shifted upward as depicted by the curves 2a, 2b when the Igmcp1 is increased from zero (in the same manner as in FIG. 2). Then, the curve “1” is shifted to the left as depicted by the curves 4a, 4b when the K is increased from zero.

Therefore, the Rmos characteristic can be changed from the initial curve 1 to some degrees. In this point of view, if the Rmos characteristic is fluctuated, the fluctuation of the Rmos characteristic can be compensated. Since the function of the Igmcp1 for the Rmos characteristic is different from the function of the K for the Rmos characteristic, the fluctuation compensation can be enhanced if the Igmcp1 and the K can be controlled independently. Moreover, if the typical values of the Igmcp1 and K are determined and the Igmcp1 and K can be decreased from the typical values, the fluctuation compensation can be enhanced.

### Third Embodiment

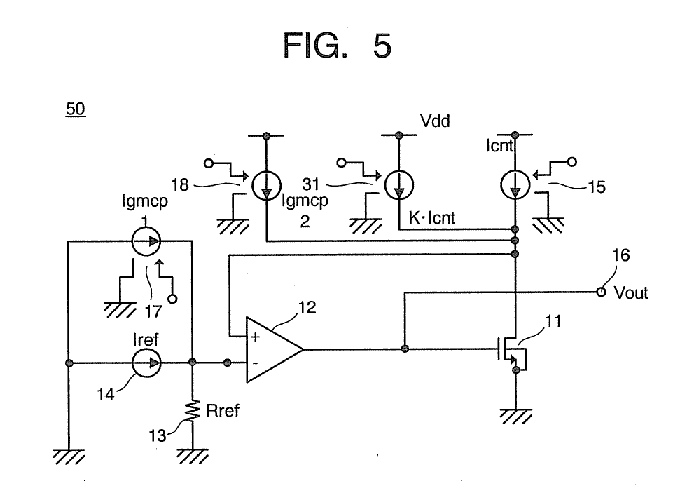

The third embodiment will be described with reference to the drawings. FIG. 5 is a circuit diagram relating to a MOS resistance controlling device according to the third embodiment. In this embodiment, like or corresponding component are designated by the same references and thus, omitted in explanation.

In the MOS resistance controlling device 50 in this embodiment, the voltage controlling current source 31 (KIcnt) is connected in series with the voltage controlling current source 15 in addition to the voltage controlling current source 18 (Igmcp2). Namely, this embodiment is combined with the first embodiment and the second embodiment so that the function/effect of this embodiment is also combined with the function/effect of the first embodiment and the function/effect of the second embodiment.

In this case, the relation of the Rmos=Rref(Iref+Igmcp1)/{(1+K)Icnt+Igmcp2} is provided. The Igmcp1, Igmcp2 and K can affect the Rmos characteristic as described above. However, since the Igmcp1, Igmcp2 and K are provided, the fluctuation compensation can be more enhanced than the one in the first embodiment and the second embodiment.

### Fourth Embodiment

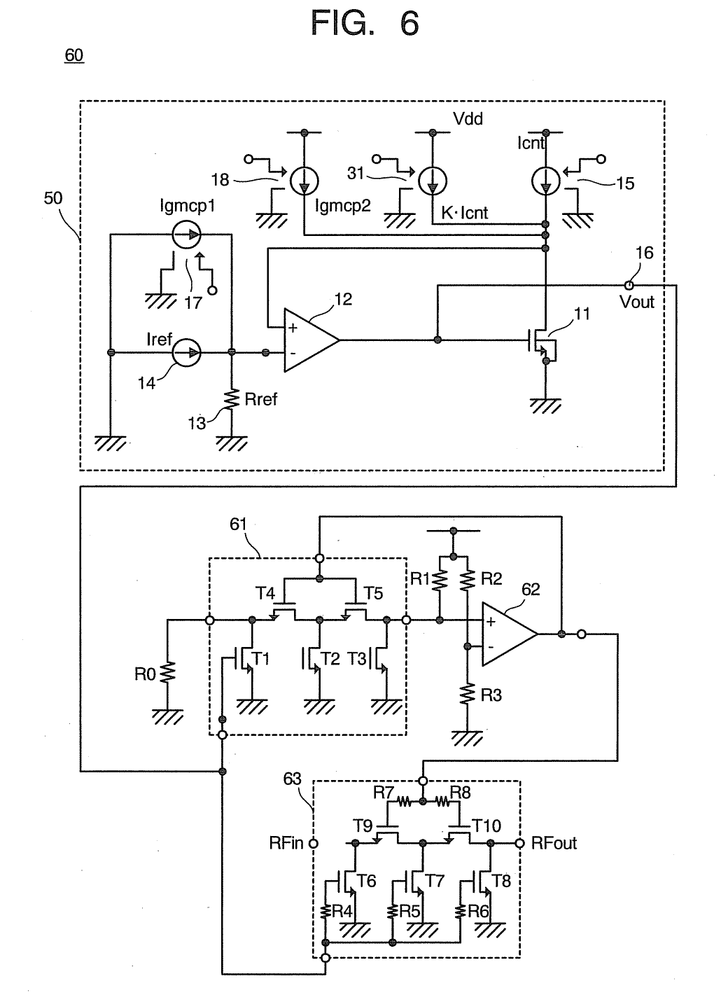

Then, a MOS attenuator will be described hereinafter. FIG. 6 is a circuit diagram relating to a MOS attenuator according to an embodiment. In this embodiment, like or corresponding component are designated by the same references and thus, omitted in explanation.

In this embodiment, the MOS attenuator 60 includes the MOS resistance controlling device 50 shown in FIG. 5. Therefore, the attenuation of the MOS attenuator 60 can be controlled by changing the output current Icnt of the voltage controlling current source 15. The MOS attenuator 60 also includes a dummy attenuator (replica) 61 with MOS transistors and a real attenuator 62 with MOS transistors for passing signals in addition to the MOS resistance controlling device 50.

With the dummy attenuator 61, a resistance R0 corresponding to the impedance of a signal source is connected to the input terminal thereof. The one end of the resistance R0 is electrically grounded (third standard potential). Then, a resistance R1 corresponding to the terminating resistance is connected to the output terminal thereof. The one end of the resistance R1 is electrically connected to the Vdd (fourth standard potential). In this case, the resistance R1 may be set different from the resistance R0. In the dummy attenuator 61, ground MOS transistors T1, T2, T3 and-passing MOS transistors T4, T5 are provided. The output voltage of the MOS resistance controlling device 50 is supplied to the gates of the ground MOS transistors T1, T2, T3, respectively. Then, the output of the operational amplifier 62 is supplied to the gates of the passing MOS transistors T4, T5 so that the characteristic impedance of the dummy attenuator 61 can be set to a predetermined value.

The real attenuator 63 is structured in the same manner as the dummy attenuator 61 (so as to contain MOS transistors T6, T7, T8, T9, T10). The resistances R4, R5, R6, R7 and R8, which are connected to the gates of the MOS transistors T6, T7, T8, T9 and T10, respectively, reduce high frequency signals input into the attenuator 63. Therefore, the high frequency signals can be reduced remarkably through the attenuator 63. Then, the output voltage of the MOS resistance controlling device 50 is supplied to the gates of the ground MOS transistors T6, T7, T8 and the output of the operational amplifier 62 is supplied to the gates of the MOS transistors T9, T10, as in the dummy attenuator 61.

The output terminal of the dummy attenuator 61 is connected with the resistance R1 and the non-inverting input terminal of the operation amplifier 62. The voltage generated at the node between the resistances R2 and R3 is supplied to the inverting input terminal of the operational amplifier 62. In this case, since the input terminals of the operational amplifier 62 are shorted imaginarily, the output of the operational amplifier 62 is fed back to the dummy attenuator 61 (concretely, to the gates of the MOS transistors T4, T5) so that the resistance R3 is provided imaginarily in the attenuator 61 when the resistance R1 is set equal to the resistance R2. Therefore, if the resistance R3 and R0 are set to a predetermined characteristic impedance, the characteristic impedance of the attenuator 61 can be set to the predetermined characteristic impedance. In this case, the characteristic impedance of the attenuator 63 is also set to the predetermined characteristic impedance.

Since the resistance R2 and the resistance R3 are connected with one another so as to constitute a voltage dividing circuit, the resistance R2 and the resistance R3 may be multiplied by a given coefficient so as to realize the reduction of the consumption current. In this case, the relation of R1=R2 is not satisfied so that the resistance R3 is shifted from the above-described characteristic impedance.

In the MOS attenuator 60 as shown in FIG. 6, the output voltage of the MOS resistance controlling device 50 is supplied to the gates of the MOS transistors T1, T2, T3, T6, T7, T8 in the attenuator 61 and 63. Therefore, the resistances corresponding to the resistance Rmos of the MOS transistor 11 are generated based on the output current Icnt of the voltage controlling current source 15. Preferably, the MOS resistance controlling device 50 is provided in the vicinity of the attenuators 61 and 63 so that the MOS transistors 11 in the device 50 can be related with the MOS transistors T1, T2, T3, T6, T7, T8.

The MOS transistor T2 is shared with two sets of a circuits in the dummy attenuator 61 and the MOS transistor T7 is shared with two sets of π circuits in the real attenuator 63. Therefore, it is desired that the MOS resistance of the MOS transistor T2 and/or T7 is decreased half as large as the MOS resistance of the MOS transistors T1, T3 and/or T6, T8 by increasing the size (gate width) of the MOS transistor T2 and/or T7 twice as large as the sizes (gate widths) of the MOS transistors T1, T3 and/or T6, T8. In this case, the current density in the MOS transistor T2 and/or T7 can be set equal to the current density in the MOS transistors T1, T3 and/or T6, T8.

Under the above-described condition, the attenuation “A” of the RFin through the RFout in the attenuator 63 can be represented by the equation of “A”={(Rshunt−Z0)/(Rshunt−Z0)}². Herein, the Rshunt is equal to the Rmos of the ground MOS transistors T6 and T8 (twice as large as the Rmos of the MOS transistor T7), and Z0 is a characteristic impedance. If rewritten in dB, the equation can be represented as “A (dB)”=20 log {(Rmos−Z0)/(Rmos−Z0)}². If the equation of Rmos=Rref(Iref+Igmcp1)/{(1+K)Icnt+Igmcp2} is substituted, the equation can be represented as “A (dB)”=20 log [(Rref(Iref+Igmcp1)/{(1+K)Icnt+Igmcp2}−Z0)/(Rref(Iref+Igmcp1)/{(1+K)Icnt+Igmcp2}−Z0)]². The MOS attenuator 60 is configured such that the output current Icnt of the voltage controlling current source 15 is input and the attenuation value of the attenuator 63 is output.

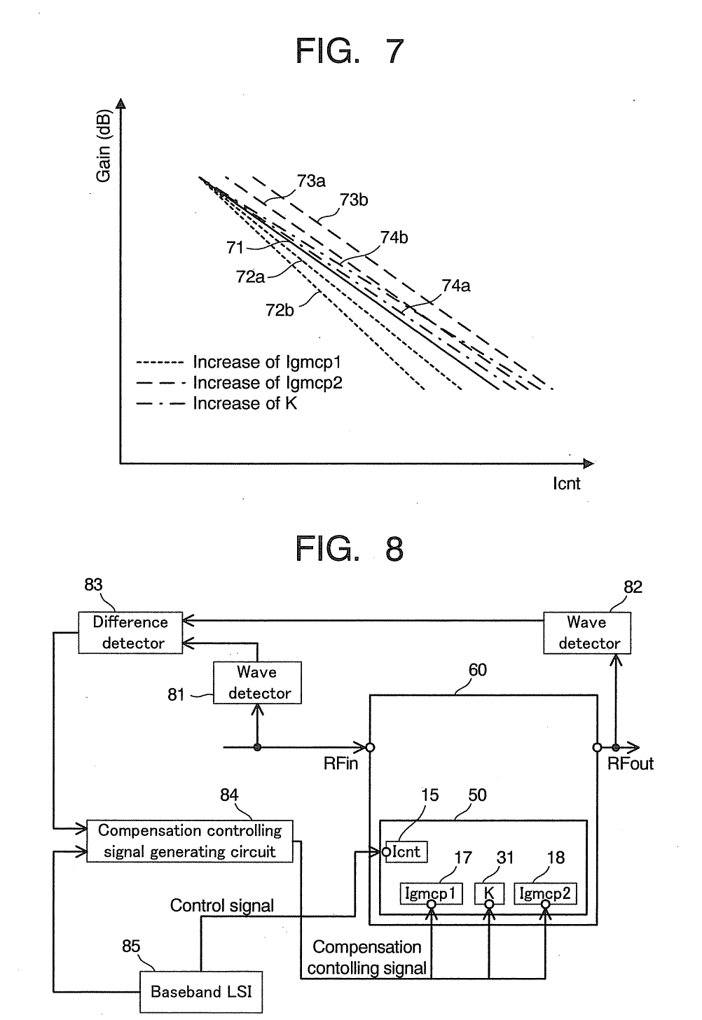

According to the above equation, the characteristic of the Icnt vs the attenuation value (gain) can be depicted as the line 71 in FIG. 7. Strictly, the line 71 is not linear, but can be considered linear within a predetermined range. When the Igmcp1 is increased from zero, the gradient of the line 71 is also increased so that the line 71 can be shifted to the lines 72a, 73b . . . . When the K is increased from zero, the gradient of the line 71 is decreased. Then, when the Igmcp2 is increased from zero, the line 71 is shifted upward and depicted as the line 73a, 73b . . . (i.e., the y-intercept is increased).

Namely, in the MOS attenuator 60, when the initial characteristic of the Icnt vs the attenuation value (gain) depicted by the line 71 is shifted from the designed characteristic, the characteristic of the Icnt vs the attenuation value (gain) can be set as designed by controlling the Igmcp1, Igmcp2 and K. Therefore, the fluctuation in the characteristic of the Icnt vs

### Fifth Embodiment

Then, another MOS attenuator will be described with reference to FIG. 8. FIG. 8 is a block diagram showing the compensation in variable attenuation characteristic of the MOS attenuator 60 in FIG. 6. The attenuator 60 is configured such that the Igmcp1, Igmcp2 and K can be controlled. In this embodiment, like or corresponding component are designated by the same references and thus, omitted in explanation.

As shown in FIG. 8, the MOS attenuator in this embodiment includes wave detectors 81, 82, a difference detector 83, a compensation controlling signal generating circuit 84 and a baseband LSI (baseband signal processing unit) 85. The baseband LSI 85 is provided in view of the application of the MOS attenuator as a wireless transmitter. The baseband LSI 85 functions as processing a signal to be transmitted. Then, the baseband LSI 85 outputs a controlling signal to the MOS attenuator 60 so as to control the Icnt. Then, the information signal relating to the controlling signal is supplied to the compensation controlling signal generating circuit 84 from the baseband LSI 85 as shown in FIG. 8.

The wave detector 81 detects the RFin (input signal) of the MOS attenuator 60 and supplies the resultant detected wave output to the difference detector 83 via one input terminal thereof. The wave detector 82 detects the RFout (output signal) of the MOS attenuator 60 and supplies to the resultant detected wave to the difference detector 83 via the other input terminal thereof. The wave detectors 81 and 82 may be configured as peak detector circuits containing (a) diode(s), respectively. The difference detector 83 calculates the difference between the signal from the wave detector 81 and the signal from the wave detector 82. In this case, the signal difference corresponds to the attenuation of the MOS attenuator 60. In this way, the wave detectors 81, 82 and the difference detector 83 function as an attenuation detector in the MOS attenuator 60.

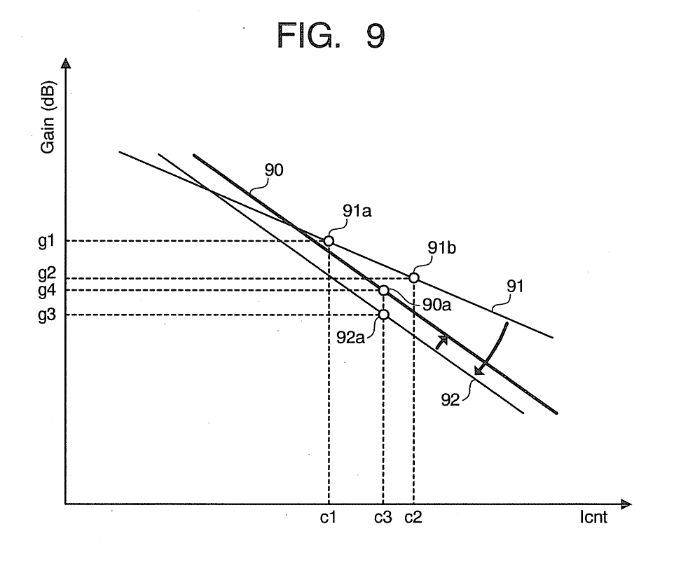

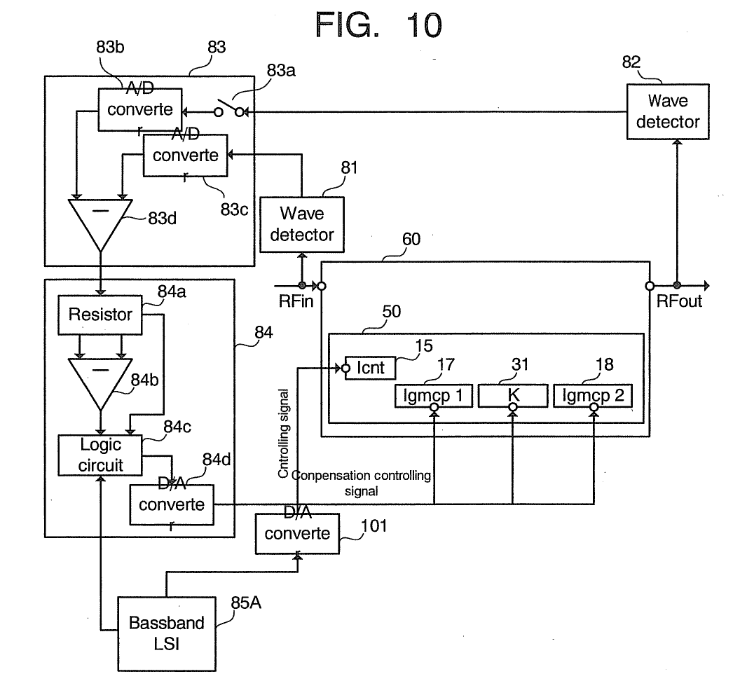

The signal difference calculation is conducted at least twice by changing the controlling signal of the Icnt from the baseband LSI 85 so that the characteristic line of the Icnt vs the attenuation value (gain) can be obtained. Concretely, refer to FIG. 9. FIG. 9 is a graph showing the compensation in variable attenuation characteristic of the MOS attenuator by the block diagram shown in FIG. 8. First of all, the Icnt from the baseband LSI 85 is set to c1 and then, the attenuation value g1 is obtained as a signal difference at the difference detector 83. In this case, the plot 91a can be obtained in FIG. 9. Then, the Icnt from the baseband LSI 85 is set to c2 and then, the attenuation value g2 is obtained as a signal difference at the difference detector 83. In this case, the plot 91b can be obtained in FIG. 9. Therefore, the characteristic line can be obtained as the line 91 passing through the plots 91a and 91b.

Whether the gradient of the line 91 is set as designed can be determined by the compensation controlling signal generating circuit 84 if the compensation controlling signal generating circuit 84 contains the information of the designed gradient relating to C1 and c2. The information relating to C1 and c2 can be obtained from the baseband LSI 85. When the gradient of the line 91 is different from the designed gradient thereof, the compensation controlling signal generating circuit 84 generates the signal relating to the increase/decrease of the Igmcp1 and/or K as a part of the compensation controlling signal. As described above, the gradient of the line 91 is increased on the compensation controlling signal when the gradient of the line 91 is set smaller than the designed gradient of the line 91 and the gradient of the line 91 is decreased on the compensation controlling signal when the gradient of the line 91 is set larger than the designed gradient of the line 91. In this way, the attenuation characteristic of the MOS attenuator is shifted to the designed attenuation characteristic.

The gradient control of the attenuation characteristic can be conducted several times. Alternatively, the information relating to the preferable variation of the Igmcp1 and/or K can be stored in the compensation controlling signal generating circuit 84 so as to decrease the number of the gradient control. The line 91 is shifted to the line 92, for example by the gradient control of the attenuation characteristic.

Then, the Icnt from the baseband LSI 85 is set to c3 and then, the attenuation value g3 is obtained as a signal difference at the difference detector 83. In this case, the plot 92a can be obtained in FIG. 9.

Whether the gradient of the line 92 is set as designed can be determined by the compensation controlling signal generating circuit 84 if the compensation controlling signal generating circuit 84 contains the information g4 of the attenuation relating to C3. The information relating to C3 can be obtained from the baseband LSI 85. When the line 92 is not positioned vertically as designed in FIG. 9, the compensation controlling signal generating circuit 84 generates the signal relating to the increase of the Igmcp2 as a part of the compensation controlling signal. Therefore, the line 92 can be positioned vertically as designed.

The vertical position control of the attenuation characteristic can be conducted several times. Alternatively, the information relating to the preferable Igmcp2 for the attenuation g3 can be stored in the compensation controlling signal generating circuit 84 so as to decrease the number of the vertical position control. The line 92 is shifted to the line 90, for example by the vertical position control of the attenuation characteristic.

As described above, the compensation controlling signal generating circuit 84 function as a signal generating unit to generate the controlling signals for the Igmcp1, Igmcp2 and K. In this embodiment, the attenuation characteristic is shifted upward by increasing the Igmcp2. If the Igmcp2 is set within a given range, the attenuation characteristic can be upward or downward by increasing or decreasing the Igmcp2. As a result, even though the gradient of the attenuation characteristic is set smaller or larger than a prescribed gradient of the attenuation and/or the position of the attenuation characteristic is shifted vertically from a prescribed position, the fluctuation of the attenuation characteristic relating to the gradient and/or position thereof can be compensated so that the attenuation characteristic of the MOS attenuator can be set as designed.

In the case that the input level at the input terminal of the MOS attenuator 60 is already known (e.g., constant), the attenuation of the MOS attenuator 60 can be detected substantially by introducing the signal from the wave detector 82 to the difference detector 83 without the wave detector 81.

### EXAMPLE 1

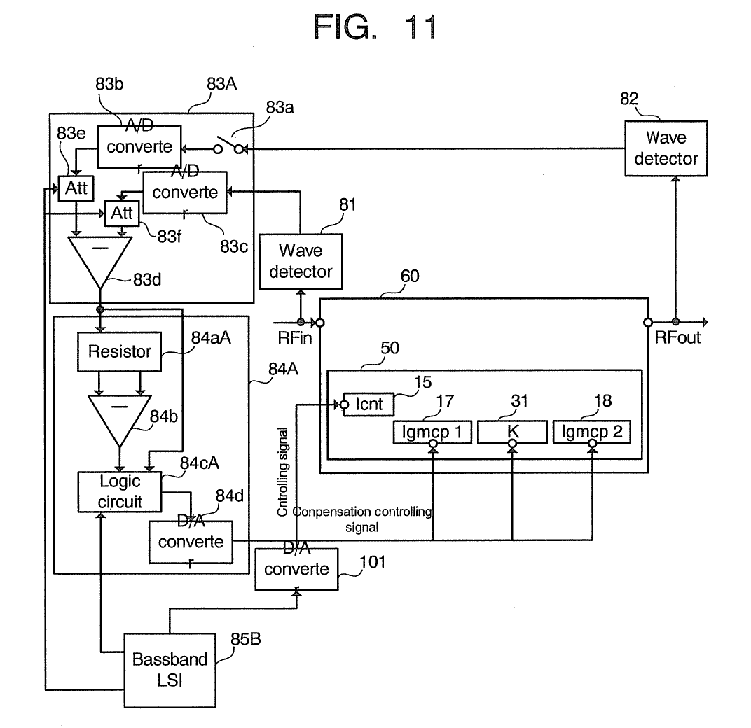

FIG. 10 is a block diagram showing a concrete embodiment of the block diagram of the MOS attenuator shown in FIG. 8. Like or corresponding component are designated by the same references and thus, omitted in explanation. In Example 1, the difference detector 83 includes a switch 83a, analog/digital converters 83b, 83c and a subtracter 83d, and the compensation controlling signal generating circuit 84 includes a resistor 84a, a subtracter 84b, a logic circuit 84c and a digital/analog converter 84d. Moreover, a digital/analog converter 101 so as to convert a digital controlling signal to the voltage controlling current source 15 from the baseband LSI 85A into the corresponding analog controlling signal is provided.

The difference detector 83 and the compensation controlling signal generating circuit 84 conduct digital processing entirely. Therefore, the resultant detected wave output from the wave detector 81 is converted into the corresponding digital signal at the analog/digital converter 83c. Then, the resultant detected wave output from the wave detector 82 is converted into the corresponding digital signal at the analog/digital converter 83b via the switch 83a. The signal difference between the digital signals obtained at the analog/digital converter 83c and at the analog/digital converter 83b is calculated at the subtracter 83d, and stored digitally as the attenuation values g1, g2, g3 in the resistor 84a (refer to FIG. 9).

The digital attenuation values g1 and g2 stored in the resistor 84a are subtracted at the subtracter 84b so that the gradient of the attenuation characteristic line relating to the digital attenuation values g1 and g2 is obtained. Then, the logic circuit 84c generates a given digital signal to increase/decrease the Igmcp1 and/or K as a part of the compensation controlling signal so that the gradient of the attenuation characteristic line 91 can be set as designed. The digital compensation controlling signal is converted into the corresponding analog signal at the digital/analog converter 84d, and then, supplied to the voltage controlling current source 17 and/or the voltage controlling current source 31.

Then, the digital attenuation value g3 stored in the resistor 84a is supplied to the logic circuit 84c. Then, the logic circuit 84c generates a given digital signal to increase/decrease the Igmcp2 as a part of the compensation controlling signal so that the attenuation characteristic line can be positioned vertically as designed (refer to FIG. 9). The digital compensation controlling signal is converted into the corresponding analog signal at the digital/analog converter 84d, and then, supplied to the voltage controlling current source 18.

In this way, the logic circuit 84c functions as a digital output converting unit to output a predetermined digital value commensurate with the digital difference at the subtracter 84b and as a digital converting unit to output a predetermined digital value commensurate with the digital attenuation value g3.

In FIG. 10, the difference detector 83 and the compensation controlling signal generating circuit 84 are digitized so that the detection error and the compensation error can be reduced in comparison with the analog difference detector and the analog compensation controlling signal generating circuit. Moreover, the analog/digital converters 83b, 83c and the like are required in specific use (i.e., the compensation of the MOS attenuator 60) and thus, may be shared with other components in another circuit. As a result, the circuit dimension as shown in FIG. 10 can be reduced. Then, the components of the circuit shown in FIG. 10 can be constituted from the elements manufactured by means of CMOS process, and thus, easily integrated as one chip. As a result, the application device containing the circuit as shown in FIG. 10 and the corresponding MOS attenuator can be downsized. The difference detector 83 and the compensation controlling digital generating circuit 84 may be contained in the baseband LSI 85A.

### EXAMPLE 2

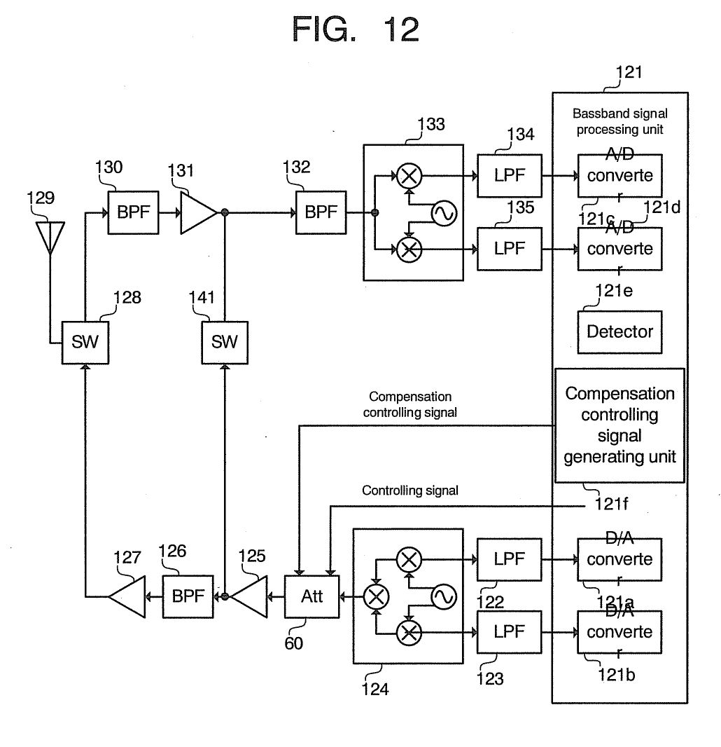

FIG. 11 is a block diagram showing another concrete embodiment of the block diagram of the MOS attenuator shown in FIG. 8. Like or corresponding component are designated by the same references and thus, omitted in explanation. In Example 2, the difference detector 83A, which is modified from the difference detector 83, includes digital attenuators 83e, 83f in addition to the switch 83a, the analog/digital converters 83b, 83c and the subtracter 83d. Then, the compensation controlling signal generating circuit 84A, which is modified from the compensation controlling signal generating circuit 84, includes a resistor 84aA, the subtracter 84b, a logic circuit 84cA and the digital/analog converter 84d. Moreover, a controlling signal relating to the attenuation value is supplied to the digital attenuators 83e and 83f from the baseband LSI 85B.

In this Example, the logic circuit 84cA generates a given digital signal to increase/decrease the Igmcp1 and/or K as a part of the compensation controlling signal in view of the digital attenuation values g1 and g2 stored in the resistor 84aA in the same manner as in Example 1. In this case, the digital attenuators 83e and 83f are controlled by the baseband LSI 85B so as not to be functioned as attenuators, respectively (in this case, a signal is passed through the digital attenuators 83e and 83f under the condition of no attenuation).

In this Example, the attenuation of the digital attenuator 83f positioned between the analog/digital converter 83c and the subtracter 83d is controlled commensurate with the designed attenuation so that a given digital value can be obtained as a standard of zero, instead of the obtaining the attenuation value g3 as an output from the substracter 83d (refer to FIG. 9). Referring to the digital value as the standard of zero, therefore, it is turned out whether the attenuation characteristic line is positioned above or below the designed position. Therefore, the logic circuit 84cA generates a predetermined digital value commensurate with the digital value as the standard of zero. Since the functional load of the logic circuit 84cA becomes smaller than the functional load of the logic circuit 84c as shown in FIG. 8, the circuit dimension as shown in FIG. 11 can be reduced. Since the digital attenuator 83e is a dummy attenuator for the digital attenuator 83f, the digital attenuator 83e is not required to be controlled.

The vertical position control of the attenuation characteristic may be conducted several times until the attenuation value as the standard of zero can be smaller than the predetermined value. Alternatively, the information relating to the preferable variation of the Igmcp2 can be stored in the logic circuit 84cA so as to decrease the number of the vertical position control.

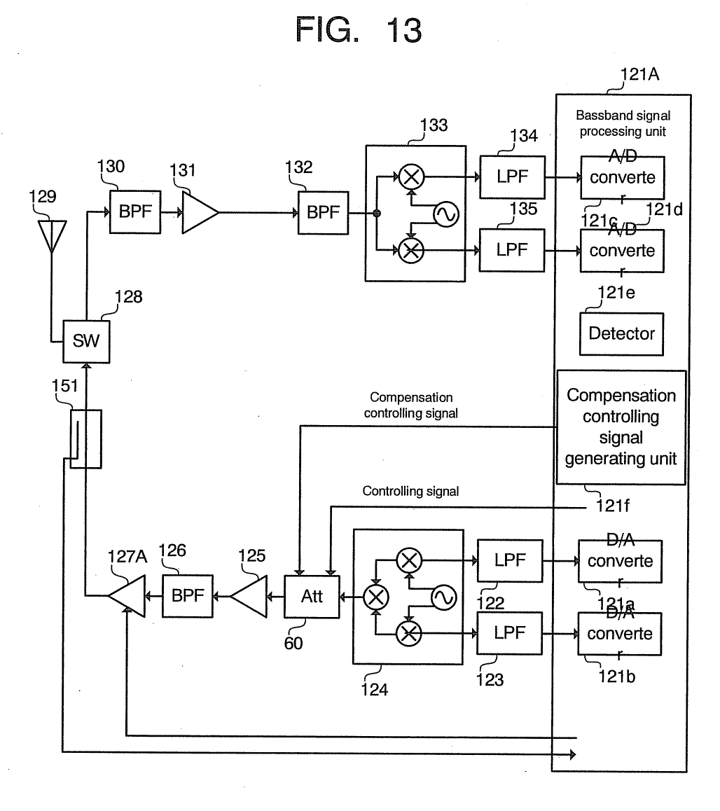

Then, an application of the MOS attenuator will be described. The MOS attenuator may be applied for a wireless transmitter such as a cellular phone or a wireless receiver. FIG. 12 is a block diagram showing the structure of a wireless transmitter having the MOS attenuator shown in FIG. 6. In this embodiment, like or corresponding component are designated by the same references and thus, omitted in explanation. In this embodiment, TDD (time division duplex) method to conduct the transmission/reception switching under time division is employed, but the transmission/reception switching method is not restricted. For example, FDD (frequency division duplex) method may be employed.

As shown in FIG. 12, the wireless transmitter/receiver includes a baseband signal processing unit 121, LPFs 122, 123, a quadrature modulator 124, the MOS attenuator 60, a driver 125, a BPF 126, an electric power amplifier 127, a transmission/reception switch 128, an antenna 129, a band-pass filter 130, a low noise amplifier 131, a band-pass filter 132, a quadrature demodulator 133, LPFs 134, 135, and a calibration switch 141. The baseband signal processing unit 121 includes at least digital/analog converters 121a, 121b to output analog signals to be input into the LPFs 122, 123, analog/digital converters 121c, 121d to convert the analog signals from the LPFs 134, 135 into the corresponding digital signals, a detector 121e to detect a value corresponding to the attenuation value in the MOS attenuator 60, and a compensation controlling signal generating unit 121f to generate control signals for the Igmcp1, K, Igmcp2.

Then, the operation of the wireless transmitter/receiver will be described with the functions of the components composing the wireless transmitter/receiver. At transmission, some processings are conducted in the baseband signal processing unit 121 so as to generate a transmission signal. At the last processing at the digital/analog converters 121a and 121b, the transmission signal is converted into the corresponding analog signal. In this case, the thus obtained baseband analog signal is restricted within a predetermined frequency range at the LPFs 122 and 123. The baseband signal is introduced into the quadrature modulator 124 to modulate the orthogonal carriers. In this case, the orthogonal carriers are combined at the same time as the modulation and then, supplied as a modulated signal to the MOS attenuator 60.

The MOS attenuator 60 attenuates the modulated signal. The attenuated and modulated signal is amplified at the driver 125 so as to operate the BPF 126, and introduced into the electric power amplifier 127 through the BPF 126. The attenuated and modulated signal is amplified in electric power at the electric power amplifier 127. The modulated signal with the amplified electric power is supplied to the antenna 129 by switching the transmission/reception switch 128 to the transmission side. Then, the modulated signal is emitted as a radio wave from the antenna 129.

At reception, a radio wave traveling in air is received at the antenna 129 and introduced as an RF signal into the band-pass filter 130 by switching the transmission/reception switch 128 to the reception side. Unnecessary frequency components are removed from the RF signal at the band-pass filter 130, and the thus obtained RF signal output from the band-pass filter 130 is amplified at the low noise amplifier 131 under low noise condition. The amplified RF signal under low noise condition is introduced into the band-pass filter 132 so as to remove the unnecessary frequency components therefrom. The thus obtained RF signal output from the band-pass filter 132 is input into the quadrature demodulator 133.

The quadrature demodulator 133 demodulates the RF signal using two orthogonal axes relating to two local carrier waveform. Then, unnecessary frequency components are removed from the thus demodulated signal at the LPFs 134 and 135. Then, the demodulated signal is introduced into the baseband processing unit 121 so as to be digitized at the analog/digital converters 121c, 121d and processed in baseband.

In addition to the above-described normal processings, in this wireless transmitter/receiver, the attenuation characteristic of the MOS attenuator 60 is calibrated. In this point of view, the baseband signal processing unit 121 includes the detector 121e and the compensation controlling signal generating unit 121f. Then, the calibration switch 141 is provided so as to introduce the output from the transmission driver 125 into the reception BPF 132. The switch 141 is off (opened) at normal state and on (closed) at calibration state. At the on-state of the switch 141, the output of the driver 125 is input into the BPF 132. At the calibration-state of the switch 141, no signal is input the BPF 132 from the low noise amplifier 131 because no radio wave is received at the antenna 129.

According to the calibration structure, the attenuation characteristic of the MOS attenuator 60 is compensated so that the controlling characteristic of the baseband signal processing unit 121 for the MOS attenuator 60 is stabilized. The concrete calibration process will be described hereinafter.

The detector 121e corresponds to the difference detector 83 in the embodiment relating to FIG. 8, and the compensation controlling signal generating unit 121f corresponds to the compensation controlling signal generating circuit 84. In this embodiment, the input signal for the MOS attenuator 60 is substituted (estimated) with the input signal for the digital/analog converters 121a, 121b, and the output signal for the MOS attenuator 60 is substituted with the signal returned into the baseband signal processing unit 121 from the MOS attenuator 60 through the driver 125, the switch 141, the BPF 132, the quadrature demodulator 133, the LPFs 134, 135. On the contrary, in the embodiment relating to FIG. 8, the input signal and the output signal for the MOS attenuator are directly detected.

As described above, in this embodiment, the switch 141 is additionally provided in not view of the concrete structure of the baseband signal processing unit 121 so as to conduct the calibration of the attenuation characteristic of the MOS attenuator 60. Therefore, the calibration of the attenuation characteristic of the MOS attenuator 60 can be easily conducted by modifying the original circuit structure at minimum. Herein, a feedback circuit may be provided so as to feed back the output of the driver 125 (corresponding to the input for the electric current amplifier 127) to the baseband signal processing unit 121.

Then, another application of the MOS attenuator will be described. FIG. 13 is a block diagram showing the structure of another wireless transmitter having the MOS attenuator shown in FIG. 6. In this embodiment, like or corresponding component are designated by the same references and thus, omitted in explanation. In this embodiment, TDD (time division duplex) method to conduct the transmission/reception switching under time division is employed, but the transmission/reception switching method is not restricted. For example, FDD (frequency division duplex) method may be employed.

In this embodiment, the electric power amplifier 127A is configured so as to contain variable amplifying function, and a directional coupler 151 is provided at the output side of the electric power amplifier 127A. In this embodiment, the calibration switch 141 is removed because the calibration of the attenuation characteristic of the MOS attenuator 60 can be conducted by detecting a signal corresponding to the output signal for the MOS attenuator 60 with the directional coupler 151.

The electric power amplifier 127A with the variable amplifying function and the directional coupler 151 provided at the output side of the electric power amplifier 127A are well known as a transmission electric power controlling structure in FDD system and/or W-CDMA system. Namely, in the transmission electric power controlling structure, the spectral separation of the transmission electric power is received at the directional coupler 151 provided at the output side of the electric power amplifier 127A, and the information relating to the spectral separation is supplied to the baseband signal processing unit 121A so that the amplification of the electric power amplifier 127A can be controlled to a desired amplification by the baseband signal processing unit 121A.

In this embodiment, the transmission electric power controlling structure is utilized for the calibration of the MOS attenuator 60. Namely, the output signal for the MOS attenuator 60 is substituted (estimated) with a signal to be detected at the directional coupler 151, and the input signal for the MOS attenuator 60 is substituted (estimated) with the input signal for the digital/analog converters 121a, 121b as the embodiment relating to FIG. 12.

In the wireless transmitter/receiver as shown in FIG. 12 or 13, the MOS attenuator 60 is provided at the output side of the quadrature modulator 124 and the input side of the driver 125. However, the MOS attenuator 60 may be disposed at another site in the transmission processing path or reception processing path. In these cases, the calibration of the attenuation characteristic (gain controlling characteristic) of the MOS attenuator 60 can be conducted.

Although the present invention was described in detail with reference to the above examples, this invention is not limited to the above disclosure and every kind of variation and modification may be made without departing from the scope of the present invention. For example, some constituents in one embodiment may be combined with some constituents in another embodiment. Moreover, some constituents in one embodiment may be omitted appropriately.

What is claimed is:

1. A MOS resistance controlling device, comprising:
a MOS transistor of which a source is electrically connected with a first standard potential;
a first controlling current source which is disposed between and connected with a drain of the MOS transistor and a second standard potential;
an operational amplifier having a first input terminal, a second input terminal and an output terminal such that the first input terminal is connected with a connection node between the drain of the MOS transistor and the first controlling current source and the output terminal is connected with a gate of the MOS transistor;
an impedance element of which one end is connected with the second input terminal of the operational amplifier;
a standard current source for introducing a first current into the impedance element via the one end of the impedance element;
a second controlling current source for introducing a second current into the impedance element via the one end of the impedance element; and
a third controlling current source for introducing a third current into the drain of the MOS transistor.

2. The device as set forth in claim 1,
wherein the first controlling current source and the third controlling current source are configured as voltage controlling current sources, respectively,
wherein a transconductance of the third controlling current source is set coefficient times as large as a transconductance of the first controlling current source.

3. The device as set forth in claim 2, further comprising:
a fourth controlling current source for introducing a fourth current to the drain of the MOS transistor.

4. The device as set forth in claim 1,
wherein an electric potential of the first input terminal of the operational amplifier is set equal to an electric potential of the second input terminal of the operational amplifier.

5. A MOS attenuator, comprising:
a MOS transistor of which a source is electrically connected with a first standard potential;
a first voltage controlling current source which is disposed between and connected with the drain of the MOS transistor and a second standard potential;
a first operational amplifier having a first input terminal, a second input terminal and an output terminal such that the first input terminal is connected with a connection node between the drain of the MOS transistor and the first controlling current source and the output terminal is connected with a gate of the MOS transistor;
an impedance element of which one end is connected with the second input terminal of the first operational amplifier;
a standard current source for introducing a first current into the impedance element via the one end of the impedance element;
a second voltage controlling current source for introducing a second current into the impedance element via the one end of the impedance element;
a third voltage controlling current source for introducing a third current into the drain of the MOS transistor;
a fourth voltage controlling current source for introducing a fourth current to the drain of the MOS transistor, a transconductance of the fourth voltage controlling current source being set coefficient times as large as a transconductance of the first voltage controlling current source;
a first attenuator having an input terminal, an output terminal, a plurality of ground MOS transistors and at least one passing MOS transistor, the ground MOS transistors and the passing MOS transistor being disposed between the input terminal and the output terminal of the first attenuator, so that the output terminal of the first operational amplifier is connected with gates of the ground MOS transistors and a control voltage is supplied to a gate of the at least one passing MOS transistor so as to set a characteristic impedance between the input terminal and the output terminal to a predetermined value;
a first resistor, electrically disposed between the input terminal of the first attenuator and a third reference potential, having an impedance corresponding to the characteristic impedance;
a second resistor, electrically disposed between the output terminal of the first attenuator and a forth reference potential;
a second operational amplifier to generate an amplified output signal in comparison with a voltage at the output terminal of the first attenuator and a predetermined voltage, and to output the amplified output signal as the control voltage; and
a second attenuator having an input terminal, an output terminal, a plurality of ground MOS transistors and at least one passing MOS transistor, the ground MOS transistors and the passing MOS transistor being disposed between the input terminal and the output terminal of the second attenuator, so that the output terminal of the first operational amplifier is connected with gates of the ground MOS transistors and the control voltage is supplied to a gate of the at least one passing MOS transistor.

6. The attenuator as set forth in claim 5, further comprising:
a first detecting unit for detecting, as a first attenuation value, a signal attenuation in a first controlling voltage supplied to the first voltage controlling current source when the first controlling voltage is passed through the second attenuator via the input terminal and the output terminal of the second attenuator;
a second detecting unit for detecting, as a second attenuation value, a signal attenuation in a second controlling voltage, different from the first controlling voltage, supplied to the first voltage controlling current source when the second controlling voltage is passed through the second attenuator via the input terminal and the output terminal of the second attenuator;
a first signal generating unit for generating, as a first compensation controlling signal, a controlling voltage for the second voltage controlling current source and/or the fourth voltage controlling current source so that a difference between the first attenuation value and the second attenuation value is set to a predetermined value commensurate with the first controlling voltage and the second controlling voltage;
a third detecting unit for detecting, as a third attenuation value, a signal attenuation in a third controlling voltage supplied to the first voltage controlling current source when the third controlling voltage is passed through the second attenuator via the input terminal and the output terminal of the second attenuator; and
a second signal generating unit for generating, as a second compensation controlling signal, a controlling voltage for the third voltage controlling current source so that the third attenuation value is set to a predetermined value commensurate with the third controlling voltage.

7. The attenuator as set forth in claim 6,
wherein the first detecting unit includes a first wave detector for generating a first wave detecting output by detecting a signal at the input terminal of the second attenuator, a first analog/digital converter for converting in analog-to-digital the first wave detecting output and thus, generating a first digital wave detecting output, a second wave detector for generating a second wave detecting output by detecting a signal at the output of the second attenuator, a second analog/digital converter for converting in analog-to-digital the second wave detecting output and thus, generating a second digital wave detecting output, and a subtracter for calculating a difference between the first digital wave detecting output and the second digital wave detecting output,
wherein the second detecting unit and the third detecting unit share the first detector, the second detector, the first analog/digital converter, the second analog/digital converter and the subtracter with the first detecting unit.

8. The attenuator as set forth in claim 7,
wherein the first signal generating unit includes a second subtracter for generating, as a first digital value, a difference between the first attenuation value and the second attenuation value, a first digital output converting unit configured so as to generate a second digital value commensurate with the first digital value, and a first digital/analog converter for converting the second digital value into the corresponding analog signal as the first compensation controlling signal,
wherein the second signal generating unit includes a second digital output converting unit configured so as to generate a third digital value commensurate with the third attenuation value and a second digital/analog converter for converting the third digital value into the corresponding analog signal as the second compensation controlling signal.

9. The attenuator as set forth in claim 5, further comprising:
a first detecting unit for detecting, as a first attenuation value, a signal attenuation in a first controlling voltage supplied to the first voltage controlling current source when the first controlling voltage is passed through the second attenuator via the input terminal and the output terminal of the second attenuator;
a second detecting unit for detecting, as a second attenuation value, a signal attenuation in a second controlling voltage, different from the first controlling voltage, supplied to the first voltage controlling current source when the second controlling voltage is passed through the second attenuator via the input terminal and the output terminal of the second attenuator;
a first signal generating unit for generating, as a first compensation controlling signal, a controlling voltage for the second voltage controlling current source and/or the fourth voltage controlling current source so that a difference between the first attenuation value and the second attenuation value is set to a predetermined value commensurate with the first controlling voltage and the second controlling voltage;
a third detecting unit for detecting a difference value between a third attenuation value relating to a signal attenuation in a third controlling voltage supplied to the first voltage controlling current source when the third controlling voltage is passed through the second attenuator via the input terminal and the output terminal of the second attenuator and a predetermined value commensurate with the third controlling voltage; and
a second signal generating unit for generating, as a second compensation controlling signal, a controlling voltage for the third voltage controlling current source so that the difference value is set smaller than a predetermined value.

10. The attenuator as set forth in claim 9,
wherein the first detecting unit includes a first wave detector for generating a first wave detecting output by detecting a signal at the input terminal of the second attenuator, a first analog/digital converter for converting in analog-to-digital the first wave detecting output and thus, generating a first digital wave detecting output, a second wave detector for generating a second wave detecting output by detecting a signal at the output of the second attenuator, a second analog/digital converter for converting in analog-to-digital the second wave detecting output and thus, generating a second digital wave detecting output, and a first subtracter for calculating a difference between the first digital wave detecting output and the second digital wave detecting output,
wherein the second detecting unit shares the first detector, the second detector, the first analog/digital converter, the second analog/digital converter and the first subtracter with the first detecting unit,
wherein the third detecting unit includes a third wave detector for generating a third wave detecting output by detecting a signal at the input terminal of the second attenuator, a third analog/digital converter for converting in analog-to-digital the third wave detecting output and thus, generating a third digital wave detecting output, a digital attenuator for generating an attenuation wave detecting output from the third digital wave detecting output based on an attenuation indication signal predetermined commensurate with the third attenuation value, a fourth wave detector for generating a fourth wave detecting output by detecting a signal at the output of the second attenuator, a fourth analog/digital converter for converting in analog-to-digital the fourth digital wave detecting output and thus, generating a fourth digital wave detecting output, and a second subtracter for calculating a difference between the attenuation wave detecting output and the fourth digital wave detecting output,
wherein the first signal generating unit includes a third subtracter for generating, as a first digital value, a difference between the first attenuation value and the second attenuation value, a first digital output converting unit configured so as to generate a second digital value commensurate with the first digital value, and a first digital/analog converter for converting the second digital value into the corresponding analog signal as the first compensation controlling signal,
wherein the second signal generating unit includes a second digital output converting unit configured so as to generate a third digital value commensurate with the difference value and a second digital/analog converter for converting the third digital value into the corresponding analog signal as the second compensation controlling signal.

11. The attenuator as set forth in claim 5,
wherein an electric potential of the first input terminal of the first operational amplifier is set equal to an electric potential of the second input terminal of the first operational amplifier.

12. The attenuator as set forth in claim 5,
wherein an electric potential of the first input terminal of the second operational amplifier is set equal to an electric potential of the second input terminal of the second operational amplifier.

13. A wireless transmitter, comprising:
a baseband processing unit for generating two baseband signals;
a quadrature modulator for orthogonally modulating two carrier signals orthogonal to one another using the baseband signals and thus, generating a modulated signal;
a MOS attenuator including: a MOS transistor of which a source is electrically connected with a first standard potential; a first voltage controlling current source which is disposed between and connected with the drain of the MOS transistor and a second standard potential; a first operational amplifier having a first input terminal, a second input terminal and an output terminal such that the first input terminal is connected with a connection node between the drain of the MOS transistor and the first controlling current source and the output terminal is connected with a gate of the MOS transistor; an impedance element of which one end is connected with the second input terminal of the first operational amplifier; a standard current source for introducing a first current into the impedance element via the one end of the impedance element; a second voltage controlling current source for introducing a second current into the impedance element via the one end of the impedance element; a third voltage controlling current source for introducing a third current into the drain of the MOS transistor; a fourth voltage controlling current source for introducing a fourth current to the drain of the MOS transistor, a transconductance of the fourth voltage controlling current source being set coefficient times as large as a transconductance of the first voltage controlling current source; a first attenuator having an input terminal, an output terminal, a plurality of ground MOS transistors and at least one passing MOS transistor, the ground MOS transistors and the passing MOS transistor being disposed between the input terminal and the output terminal of the first attenuator, so that the output terminal of the first operational amplifier is connected with gates of the ground MOS transistors and a control voltage is supplied to a gate of the at least one passing MOS transistor so as to set a characteristic impedance between the input terminal and the output terminal to a predetermined value; a first resistor, electrically disposed between the input terminal of the first attenuator and a third reference potential, having an impedance corresponding to the characteristic impedance; a second resistor, electrically disposed between the output terminal of the first attenuator and a forth reference potential; a second operational amplifier to generate an amplified output signal in comparison with a voltage at the output terminal of the first attenuator and a predetermined voltage, and to output the amplified output signal as the control voltage; and a second attenuator having an input terminal, an output terminal, a plurality of ground MOS transistors and at least one passing MOS transistor, the ground MOS transistors and the passing MOS transistor being disposed between the input terminal and the output terminal of the second attenuator, so that the output terminal of the first operational amplifier is connected with gates of the ground MOS transistors and the control voltage is supplied to a gate of the at least one passing MOS transistor, the MOS attenuator being configured such that the modulated signal is input to the input terminal of the second attenuator and an attenuated and modulated signal is generated at the output terminal of the second attenuator;
an electric power amplifier for amplifying in electric power the attenuated and modulated signal and thus, generating an amplified signal in electric power; and
an antenna for emitting the amplified signal in electric power as an electromagnetic wave,
wherein the baseband signal processing unit generates a controlling voltage for the first through the fourth voltage controlling current sources.

14. The wireless transmitter as set forth in claim 13,
wherein the baseband signal processing unit includes: a first detecting unit for detecting, as a first attenuation value, a signal attenuation in a first controlling voltage supplied to the first voltage controlling current source when the first controlling voltage is passed through the second attenuator via the input terminal and the output terminal of the second attenuator; a second detecting unit for detecting, as a second attenuation value, a signal attenuation in a second controlling voltage, different from the first controlling voltage, supplied to the first voltage controlling current source when the second controlling voltage is passed through the second attenuator via the input terminal and the output terminal of the second attenuator; a first signal generating unit for generating, as a first compensation controlling signal, a controlling voltage for the second voltage controlling current source and/or the fourth voltage controlling current source so that a difference between the first attenuation value and the second attenuation value is set to a predetermined value commensurate with the first controlling voltage and the second controlling voltage; a third detecting unit for detecting, as a third attenuation value, a signal attenuation in a third controlling voltage supplied to the first voltage controlling current source when the third controlling voltage is passed through the second attenuator via the input terminal and the output terminal of the second attenuator; and a second signal generating unit for generating, as a second compensation controlling signal, a controlling voltage for the third voltage controlling current source so that the third attenuation value is set to a predetermined value commensurate with the third controlling voltage,
wherein the baseband signal processing receives, as a signal level at the output terminal of the second attenuator, a signal at an input terminal of the electric power amplifier and at the output terminal of the second attenuator.

15. The wireless transmitter as set forth in claim 13,
wherein the baseband signal processing unit includes: a first detecting unit for detecting, as a first attenuation value, a signal attenuation in a first controlling voltage supplied to the first voltage controlling current source when the first controlling voltage is passed through the second attenuator via the input terminal and the output terminal of the second attenuator; a second detecting unit for detecting, as a second attenuation value, a signal attenuation in a second controlling voltage, different from the first controlling voltage, supplied to the first voltage controlling current source when the second controlling voltage is passed through the second attenuator via the input terminal and the output terminal of the second attenuator; a first signal generating unit for generating, as a first compensation controlling signal, a controlling voltage for the second voltage controlling current source and/or the fourth voltage controlling current source so that a difference between the first attenuation value and the second attenuation value is set to a predetermined value commensurate with the first controlling voltage and the second controlling voltage; a third detecting unit for detecting a difference value between a third attenuation value relating to a signal attenuation in a third controlling voltage supplied to the first voltage controlling current source when the third controlling voltage is passed through the second attenuator via the input terminal and the output terminal of the second attenuator; a second signal generating unit for generating, as a second compensation controlling signal, a controlling voltage for the third voltage controlling current source so that the difference value is set smaller than a predetermined value,
wherein the baseband signal processing receives, as a signal level at the output terminal of the second attenuator, a signal at an input terminal of the electric power amplifier and at the output terminal of the second attenuator.

16. The wireless transmitter as set forth in claim 13,
wherein the baseband signal processing unit includes: a first detecting unit for detecting, as a first attenuation value, a signal attenuation in a first controlling voltage supplied to the first voltage controlling current source when the first controlling voltage is passed through the second attenuator via the input terminal and the output terminal of the second attenuator; a second detecting unit for detecting, as a second attenuation value, a signal attenuation in a second controlling voltage, different from the first controlling voltage, supplied to the first voltage controlling current source when the second controlling voltage is passed through the second attenuator via the input terminal and the output terminal of the second attenuator; a first signal generating unit for generating, as a first compensation controlling signal, a controlling voltage for the second voltage controlling current source and/or the fourth voltage controlling current source so that a difference between the first attenuation value and the second attenuation value is set to a predetermined value commensurate with the first controlling voltage and the second controlling voltage; a third detecting unit for detecting, as a third attenuation value, a signal attenuation in a third controlling voltage supplied to the first voltage controlling current source when the third controlling voltage is passed through the second attenuator via the input terminal and the output terminal of the second attenuator; and a second signal generating unit for generating, as a second compensation controlling signal, a controlling voltage for the third voltage controlling current source so that the third attenuation value is set to a predetermined value commensurate with the third controlling voltage,
wherein the baseband signal processing receives, as a signal level at the output terminal of the second attenuator, a signal at an output terminal of the electric power amplifier.

17. The wireless transmitter as set forth in claim 13,
wherein the baseband signal processing unit includes: a first detecting unit for detecting, as a first attenuation value, a signal attenuation in a first controlling voltage supplied to the first voltage controlling current source when the first controlling voltage is passed through the second attenuator via the input terminal and the output terminal of the second attenuator; a second detecting unit for detecting, as a second attenuation value, a signal attenuation in a second controlling voltage, different from the first controlling voltage, supplied to the first voltage controlling current source when the second controlling voltage is passed through the second attenuator via the input terminal and the output terminal of the second attenuator; a first signal generating unit for generating, as a first compensation controlling signal, a controlling voltage for the second voltage controlling current source and/or the fourth voltage controlling current source so that a difference between the first attenuation value and the second attenuation value is set to a predetermined value commensurate with the first controlling voltage and the second controlling voltage; a third detecting unit for detecting a difference value between a third attenuation value relating to a signal attenuation in a third controlling voltage supplied to the first voltage controlling current source when the third controlling voltage is passed through the second attenuator via the input terminal and the output terminal of the second attenuator; and a predetermined value commensurate with the third controlling voltage; a second signal generating unit for generating, as a second compensation controlling signal, a controlling voltage for the third voltage controlling current source so that the difference value is set smaller than a predetermined value,
wherein the baseband signal processing receives, as a signal level at the output terminal of the second attenuator, a signal at an output terminal of the electric power amplifier.
